(19) United States
(12) Patent Application Publication
(10) Pub. No.: US 2023/0242774 A1
(43) Pub. Date: Aug. 3, 2023

(54) A PHOTOPOLYMER EPOXY COMPOSITION AND A PHOTOINITIATOR FOR CURING SAME

(71) Applicant: POLYMER GVULOT LTD, M.P. Halutza (IL)

(72) Inventors: Tali OSIROFF, Ganei Tikva (IL); Tom DOLEV, Zur Izhak (IL); Ofir EREZ, Rishon LeTsiyon (IL); Yoram BEN ARI, M.P Lachish Darom (IL)

(21) Appl. No.: 17/999,879

(22) PCT Filed: May 26, 2021
(86) PCT No.: PCT/IL2021/050623

§ 371 Date: Nov. 25, 2022

(30) Foreign Application Priority Data
Jun. 1, 2020 (IL) 275026
Jul. 28, 2020 (WO) PCT/IL2020/050833
May 26, 2021 (IL) 283470

(51) Int. Cl. C09D 7/63; C09D 4/06; C09D 163/00; C09D 133/14; C09D 7/62; C09D 7/40; C09D 7/65

(52) U.S. Cl. CPC C09D 7/63; C09D 4/06; C09D 7/62; C09D 7/65; C09D 7/70; C09D 133/14; C09D 163/00

(57) ABSTRACT

A photopolymer composition comprising at least one cycloaliphatic epoxy compound and a photoinitiator comprising a triarylsulfonium salt.

### DETAILS OF RELATED APPLICATIONS

This application claims priority under the Paris convention from IL 275026 filed Jun. 1, 2020 and from IL 283470 filed May 26, 2021, each of which has the same title as the present application and each of which is fully incorporated herein by reference.

### FIELD OF THE INVENTION

The present invention relates to photopolymer compositions curable with gentle UV light. Particularly, the invention relates to fast solidifying epoxy based compositions, and to photoinitiators for use in said compositions, providing cured polymers with superior mechanical and electrical properties.

### BACKGROUND OF THE INVENTION

A photopolymerization process makes a solid polymer from a liquid radiation-curable mixture; the mixture is often called a photopolymer even if comprising only oligomers, and it is mostly cured by light irradiation in the UV range. Photon-induced crosslinking of shorter chains (curing) leads to the solidification. The photopolymer typically contains multifunctional monomers and oligomers, often comprising acrylate derivatives, and further a photoinititiator providing reactive species which start the polymerization process. The predominant mechanism of photopolymerization is based on the formation of free radicals, less frequently it comprises a cationic initiator. The curing treatment results in a solid network of thermoset polymer. The photopolymers are broadly used in medicine and dentistry, in printing, in electronics, in coating, and still more in 3D-printing.

A variety of UV curable resins have been developed, mostly employing acrylic compounds polymerized via the free radical mechanism. Many acrylic-functionalized oligomers are commercially available, including acrylated polyesters, urethanes, silicones, epoxies, and others. However, some of the compositions produce polymers prone to weathering or with a tendency to yellow - particularly in the sunlight, and other compositions exhibit lower performance in regard to the desired properties, including bond strength, solvent resistance, impact resistance, heat resistance, flexibility, glass-transition temperature (T_{g}), electrical resistivity, and other. A general problem with the free radical photopolymerization of acrylic compositions lies in their extreme sensitivity to oxygen inhibition. Compositions comprising cationic initiators, based for example on epoxy or vinyl ether compounds, have been described but few are available and, moreover, they are easily deactivated by small amounts of water. Another general difficulty with light-induced solidification is the limited light penetration depth. Further, the need for UV light, which use is strictly regulated in view of health and environmental hazards, also complicates the work with photopolymers. For example, a mercury lamp — the often employed UV source — provides UV light at wavelengths lower than 260 nm, typically in the range of 200-315 nm, which is considered to have serious effects in human. It is therefore an object of this invention to provide a composition avoiding at least some of the above drawbacks.

### SUMMARY OF THE INVENTION

It is another object of this invention to provide a composition for photopolymerization resistant to oxygen inhibition.

It is also an object of the invention to provide a cationically initiated photopolymerization containing a monomer selected from cycloaliphatic epoxy compounds.

It is a further object of this invention to provide a composition for cationically initiated photopolymerization containing a cycloaliphatic epoxy compound and a photoinitiator comprising an onium ion.

It is still another object of this invention to provide a composition curable with a light outside the wavelength range considered to have serious effects in human.

It is a further object of this invention to provide a composition for cationically initiated photopolymerization containing a cycloaliphatic epoxy compound and a photoinitiator comprising an onium ion, curable with a UV-LED.

This invention aims at providing a composition for cationically initiated photopolymerization containing a cycloaliphatic epoxy compound and a photoinitiator comprising an onium ion, curable with a UV-LED, and providing a solid polymer exhibiting good mechanical and electrical properties.

This invention also aims at providing a UV-LED curable and fast-solidifying composition based on cycloaliphatic epoxy compounds.

It is also an object of this invention to provide a composition for cationically initiated photopolymerization containing a cycloaliphatic epoxy compound and an onium ion, curable with light of a wavelength greater than 350 nm (gentle UV irradiation).

The invention further aims at providing a photoinitiator for cationic photo polymerization of epoxy-based photo-curable mixtures, providing fast mixture solidification when irradiated with a light of a wavelength greater than 350 nm.

The invention also aims at providing a photoinitiator for polymerization of epoxy-based photo-curable mixtures, comprising an aryl-onium ion.

Other objects and advantages of present invention will appear as the description proceeds.

According to one aspect of some embodiments of the invention relates to a photopolymer composition comprising at least one epoxy compound and a photoinitiator comprising a triarylsulfonium salt. In some exemplary embodiments of the invention, the epoxy compound is a cycloaliphatic epoxy compound. Alternatively or additionally, in some embodiments the cycloaliphatic epoxy compound usually constitutes 20-40 wt% and said photoinitiator usually constitutes 2-6 wt% of the composition. Alternatively or additionally, in some embodiments, the cycloaliphatic epoxy compound is 3,4-epoxycyclohexylmethyl-3′,4′-epoxycyclohexane carboxylate (EEC). In another embodiment, the invention provides a photoinitiator comprising one or more triarylsulfonium hexafluoro antimonate compounds together with a silane. In some exemplary embodiments of the invention, the silane comprises an alkysilane.Said photoinitiator comprises, in one embodiment, triarylsulfonium hexafluoro antimonate, silane, and an ester of carboxymethoxy-benzophenone with poly methyl ethylene glycol or with poly tetramethylene glycol. In some exemplary embodiments of the invention, the composition contains at least one component selected from silica, glass fiber, and aliphatic polyester polyols. In another embodiment, the photopolymer composition of the invention comprises 5-15 wt% silica. The composition of the invention usually comprises 10-30 wt% aliphatic polyester polyols. An important component for enhancing the mechanical and other properties of the final polymer are glass fibers, included according to the need in an amount of up to about 28 wt%. Alternatively or additionally, in some embodiments the photopolymer composition of the invention contains 5-15 wt% silica, 10-30 wt% aliphatic polyester polyols, up to 28 wt% glass fibers such as 10-25 wt%. Alternatively or additionally, in some embodiments the photopolymer composition of the invention may further comprise up to 0.5 wt% of dibutoxyanthracene. Alternatively or additionally, in some embodiments photopolymer composition of the invention may further comprise up to 0.5 wt%. Alternatively or additionally, in some embodiments the photopolymer composition of the invention may further comprise at least one blue dye. In one embodiment of the invention, the composition to be cured includes methylene blue (MB) as a curing indicator. The cured composition advantageously comprises a blue dye to rid the reaction mixture before curing of yellowish color, such as an ultramarine dye-based agent.

In some exemplary embodiments of the invention, the photopolymer composition of the invention may further comprise at least one bisphenol A epoxy compound, which, in another specific embodiment constitutes 20-40 wt% of the composition. In yet another specific embodiment, said bisphenol A epoxy compound is bisphenol A diglycidyl ether (BADGE). According to another embodiment, the photopolymer composition of the invention may further comprise at least acrylic compound, which, in another specific embodiment constitutes 5-10 wt% of the composition. In yet another specific embodiment, said acrylic compound is 2-(allyloxymethyl)acrylic acid methyl ester. In some exemplary embodiments of the invention, the resultant composition is UV curable. For example, UV irradiation with a wavelength greater than 350 nm, such as 365 nm or more, for example that of UV LED sources emitting light at 395 nm contribute to an increase in the rate of crosslinking which contributes to solidification. Alternatively or additionally, in some embodiments the polymer exhibits good mechanical and electrical properties (e.g. di-electric).

Another aspect of some embodiments of the invention is directed to a quickly acting photoinitiator for photopolymer compositions that comprise cycloaliphatic epoxy compounds, which in other specific embodiments may be in an amount of 20-40 wt%, the weight % being based on the composition including the initiator, and where said photoinitiator is usually employed in an amount of 2-6 wt%, weight % being based on the composition including the initiator, the initiator comprising a triarylsulfonium hexafluoro antimonate, silane, and an ester of carboxymethoxy-benzophenone with poly tetramethylene glycol.

Alternatively or additionally, in some embodiments the photopolymer compositions comprise BADGE (e.g. least 20 wt% of the composition) and/or 2-(allyloxymethyl)acrylic acid methyl ester, (e.g. at least 5 wt% of the composition). Alternatively or additionally, in some embodiments the photoinitiator comprises an antimony hexafluoride based catalyst for thermal initiated cationic polymerization. For example, in some embodiments the photoinitiator comprises at least 25 wt% triarylsulfonium hexafluoro antimonate, such as 25-45 wt%, at least 2 wt% silane, such as 2-6 wt%, at least 10 wt% ester of carboxymethoxy-benzophenone with poly tetramethylene glycol, such as 10-30 wt%, and at least 2 wt% antimony hexafluoride based catalyst for thermal initiated cationic polymerization, such as 2-6 wt%. In some exemplary embodiments of the invention, photoinitiator (PI) is resistant to oxygen inhibition and works with light of a wavelength greater than 350 nm, while enabling very quick solidification.

Another aspect of some embodiments of the invention relates to a process for manufacturing a photopolymer composition comprising at least one cycloaliphatic epoxy compound and a photoinitiator comprising a triarylsulfonium salt, the composition being fast solidifying and insensitive to oxygen, and providing a polymer with a high mechanical and dielectric strength, the process comprising the step of i) preparing a photoinitiator (QPI), mixture 1, by mixing a) 1-4 weight parts of triarylsulfonium hexafluoro antimonate in propylene carbonate 1:1, b) 0.02-0.2 weight parts of silane, c) 0.2-2 weight parts of ester of carboxymethoxy-benzophenone with poly tetramethylene glycol, and d) 0.02-0.2 weight parts of antimony hexafluoride based catalyst for thermal initiated cationic polymerization. In a specific embodiment of the invention, said process for manufacturing a photopolymer composition further comprises the steps of ii) preparing a curing indicator, mixture 2, by dissolving a blue dye in EEC; iii) preparing a color purifying solution, mixture 3, by dissolving an ultramarine blue material in a polyester polyol; iv) preparing an EEC mixture, mixture 4, by mixing 20-40 weight parts of 3,4-epoxycyclohexylmethyl-3′,4′-epoxycyclohexane carboxylate (EEC), 0.1-0.5 weigh parts of said mixture 2, up to 1 weight parts of polyether, and up to 0.4 weigh parts of dibutoxyanthracene, and intensively stirring with 1-2 weigh parts of silica; v) preparing a glycidyl silane mixture, mixture 5, by mixing 0.2-0.8 weight parts of (glycidyloxypropyl)trimethoxysilane, 10-30 weigh parts of a polyester polyol, and intensively stirring with 2-6 weight parts of silica at 150° C. for 10 to 60 minutes; and vi) combining mixtures 4 and 5 while well stirring for about 15 minutes, followed by admixing 10-25 weight parts of glass fibers, 1-3 weight parts of silica, and up to 1 weight part of said mixture 3, followed by admixing 7-30 weight parts of hydrogenated bisphenol A diglycidyl ether and, in other more specific embodiments, either or both of 7-30 weight parts of bisphenol A diglycidyl ether (BADGE) and 5-10 weight parts of 2-(allyloxymethyl)acrylic acid methyl ester, while mixing at 50° C. for about 10 minutes; followed by adding 2-8 weight parts of mixture 1 while stirring about 10 more minutes, and adjusting the final viscosity by admixing about 1-3 weight parts of silica; thereby obtaining a photocomposition for curing with a light of a wavelength greater than 350 nm.

In some exemplary embodiments of the invention, the photoinitiator in accordance with the invention, employs primarily cycloaliphatic epoxy materials, such as epoxycyclohexylmethyl epoxycyclohexane carboxylate, which avoids drawbacks of other epoxy materials, such as bisphenol A epoxy (when used as a major constituent), including limited depth of cure or low resistance to prolonged exposure to UV light. The solidification process employs thermally activated components, activated by the heat of the polymerization process. The solidification process employs mixed cation/radical initiation. These compositions include the following: Triarylsulfonium hexafluoro antimonate (THA), which may be obtained, for example, from Sigma Aldrich as 50% material in propylene carbonate. Ester of carboxymethoxy-benzophenone and poly methyl ethylene glycol or ester of carboxymethoxy-benzophenone and poly tetramethylene glycol. MB-99% Quantum blue is a curing indicator; upon full cure it changes color from blue to yellowish. Ultramarine Blue is preferred dye, to be dissolved in a dendritic polymer, such as dendritic polyester polyols, specifically a branched ester of a polyol like PEG with low fatty acids. A polyether, such as silicone free polyether. Polyester polyol, such as aliphatic polyester diol.

In some exemplary embodiments of the invention there is provided a photopolymer composition including at least one cycloaliphatic epoxy compound and a photoinitiator comprising a triarylsulfonium salt. In some embodiments the at least one cycloaliphatic epoxy compound constitutes 20-40 wt% and the photoinitiator constitutes 2-6 wt% of the composition. Alternatively or additionally, in some embodiments the cycloaliphatic epoxy compound comprises 3,4-epoxycyclohexylmethyl-3′,4′-epoxycyclohexane carboxylate (EEC). Alternatively or additionally, in some embodiments the photoinitiator comprises triarylsulfonium hexafluoro antimonate and silane. Alternatively or additionally, in some embodiments the photoinitiator comprises triarylsulfonium hexafluoro antimonate, silane, and an ester of carboxymethoxy-benzophenone with poly methyl ethylene glycol or with poly tetramethylene glycol. Alternatively or additionally, in some embodiments the composition includes at least one component selected from silica, glass fiber, and aliphatic polyester polyol. Alternatively or additionally, in some embodiments the composition includes 5-15 wt% silica, 10-30 wt% aliphatic polyester polyol, and up to 28 wt% glass fiber. Alternatively or additionally, in some embodiments the composition includes up to 0.5 wt% of dibutoxyanthracene. Alternatively or additionally, in some embodiments the composition includes up to 0.5 wt% antimony hexafluoride. Alternatively or additionally, in some embodiments the composition includes at least one blue dye.

Alternatively or additionally, in some embodiments the composition includes at least one bisphenol A epoxy compound. In some embodiments the at least one bisphenol A epoxy compound constitutes 20-40 wt% of the composition. Alternatively or additionally, in some embodiments the bisphenol A epoxy compound is bisphenol A diglycidyl ether (BADGE).

Alternatively or additionally, in some embodiments the composition includes at least one acrylic compound. Alternatively or additionally, in some embodiments the at least one acrylic compound constitutes 5-10 wt% of the composition.

Alternatively or additionally, in some embodiments the photopolymer composition the acrylic compound is 2-(allyloxymethyl)acrylic acid methyl ester.

Alternatively or additionally, in some embodiments the photopolymer composition is curable with a gentle UV irradiation.

Alternatively or additionally, in some embodiments the photopolymer composition exhibits fast solidification, and good mechanical and dielectrical properties.

In some exemplary embodiments of the invention there is provided a quickly acting photoinitiator (PI) for use in photopolymer compositions comprising at least one cycloaliphatic epoxy compound, the composition comprising a triarylsulfonium hexafluoro antimonate, silane, an ester of carboxymethoxy-benzophenone with poly methyl ethylene glycol or poly tetramethylene glycol, and antimony hexafluoride.

In some embodiments the PI includes at least 25 wt% triarylsulfonium hexafluoro antimonate, at least 2 wt% silane, at least 10 wt% ester of carboxymethoxy-benzophenone with poly tetramethylene glycol, and at least 2 wt% antimony hexafluoride.

Alternatively or additionally, in some embodiments the photopolymer composition is resistant to oxygen inhibition and curable with a light of a wavelength greater than 350 nm. Alternatively or additionally, in some embodiments the at least one cycloaliphatic epoxy compound constitutes 20-40 wt% of the composition.

Alternatively or additionally, in some embodiments the photopolymer compositions includes BADGE. In some embodiments the BADGE constitutes at least 20 wt% of the composition.

Alternatively or additionally, in some embodiments the photopolymer compositions include 2-(allyloxymethyl)acrylic acid methyl ester. In some embodiments the 2-(allyloxymethyl)acrylic acid methyl ester constitutes at least 5 wt% of the composition.

In some exemplary embodiments of the invention there is provided a process for manufacturing a photopolymer composition. In some embodiments, the photopolymer composition is fast solidifying and/or insensitive to oxygen and/or provides a polymer with a high mechanical and dielectric strength. The process includes the step i) of preparing a photoinitiator, mixture 1, by mixing a) 1-4 weight parts of triarylsulfonium hexafluoro antimonate in propylene carbonate 1:1, b) 0.02-0.2 weight parts of silane, c) 0.2-2 weight parts of an ester of carboxymethoxy-benzophenone with poly tetramethylene glycol or with poly methyl ethylene glycol, and d) 0.02-0.2 weight parts of antimony hexafluoride based catalyst for thermal initiated cationic polymerization.

In some embodiments the process includes: ii)preparing a curing indicator, mixture 2, by dissolving a blue dye in 3,4-epoxycyclohexylmethyl-3′,4′-epoxycyclohexane carboxylate;
iii) preparing a color purifying solution, mixture 3, by dissolving an ultramarine blue material in a polyester polyol;
iv) preparing a cycloaliphatic epoxy mixture, mixture 4, by mixing 204-0 weight parts of 3,4-epoxycyclohexylmethyl-3′,4′-epoxycyclohexane carboxylate, 0.1-0.5 weigh parts of said mixture 2, up to1 weight parts of a polyether, and up to 0.4 weigh parts of dibutoxyanthracene, and intensively stirring with 1-2 weigh parts of silica;
v) preparing a glycidyl silane mixture, mixture 5, by mixing 0.2-0.8 weight parts of (glycidyloxypropyl)trimethoxysilane, 10-30 weigh parts of a polyester polyol, and intensively stirring with 26- weight parts of silica at 150° C. for 10-60 minutes; and
vi) combining mixtures 4 and 5 while well stirring for about 15 minutes, followed by admixing 10-25 weight parts of glass fibers, 13- weight parts of silica, and up to1 weight part of said mixture 3, followed by admixing 7-30 weight parts of hydrogenated bisphenol A diglycidyl ether while mixing at 50° C. for about 10 minutes; followed by adding 2-6 weight parts of mixture 1 while stirring about 10 more minutes, and adjusting the final viscosity by admixing about 1-3 weight parts of silica; thereby obtaining a photocomposition for curing with a light of a wavelength greater than 350 nm, such as between 380 and 395 nm.

Alternatively or additionally, in some embodiments step vi) consists of combining mixtures 4 and 5 while well stirring for about 15 minutes, followed by admixing 10-25 weight parts of glass fibers, 1-3 weight parts of silica, and up to 1 weight part of said mixture 3, followed by admixing 7-30 weight parts of hydrogenated bisphenol A diglycidyl ether and either or both of 7-30 weight parts of bisphenol A diglycidyl ether (BADGE) and 5-10 weight parts of 2-(allyloxymethyl)acrylic acid methyl ester while mixing at 50° C. for about 10 minutes; followed by adding 2-6 weight parts of mixture 1 while stirring about 10 more minutes, and adjusting the final viscosity by admixing about 1-3 weight parts of silica.

Unless otherwise defined, all technical and scientific terms used herein have the same meaning as commonly understood by one of ordinary skill in the art to which this invention belongs. Although suitable methods and materials are described below, methods and materials similar or equivalent to those described herein can be used in the practice of the present invention. In case of conflict, the patent specification, including definitions, will control. All materials, methods, and examples are illustrative only and are not intended to be limiting.

As used herein, the terms “comprising” and “including” or grammatical variants thereof are to be taken as specifying inclusion of the stated features, integers, actions or components without precluding the addition of one or more additional features, integers, actions, components or groups thereof. This term is broader than, and includes the terms “consisting of” and “consisting essentially of” as defined by the Manual of Patent Examination Procedure of the United States Patent and Trademark Office. Thus, any recitation that an embodiment “includes” or “comprises” a feature is a specific statement that sub embodiments “consist essentially of” and/or “consist of” the recited feature.

The phrase “consisting essentially of” or grammatical variants thereof when used herein are to be taken as specifying the stated features, integers, steps or components but do not preclude the addition of one or more additional features, integers, steps, components or groups thereof but only if the additional features, integers, steps, components or groups thereof do not materially alter the basic and novel characteristics of the claimed composition, device or method.

The phrase “adapted to” as used in this specification and the accompanying claims imposes additional structural limitations on a previously recited component.

The terms “method” and “process” refers to manners, means, techniques and procedures for accomplishing a given task including, but not limited to, those manners, means, techniques and procedures either known to, or readily developed from known manners, means, techniques and procedures by practitioners of the art.

Percentages, such as percentage by weight abbreviated wt%, are W/W (weight per weight) unless otherwise indicated.

### BRIEF DESCRIPTION OF THE DRAWINGS

In order to understand the invention and to see how it may be carried out in practice, embodiments will now be described, by way of non-limiting example only, with reference to the accompanying figures, wherein:

FIG. 1. shows a schematic drawing of the synthesis production process of the nanocomposite;

FIG. 2. shows the effect of non-settling of added fillers in the formulation due to the incorporation of the nano-composite in the formulation;

FIG. 3. demonstrates the dark cure effect of the epoxy formulation; by presenting the Young modulus as a function of time following initial exposure of 20 sec to 15 mW/cm2 of UV-LED @ 395 nm under air, at RT; and

FIG. 4. thermal acceleration of the dark cure effect is demonstrated through presentation of Young modulus versus time at various temperatures, following initial exposure of 20 sec to 15 mW/cm2 of UV-LED @ 395 nm under air.

### DETAILED DESCRIPTION OF THE INVENTION

It has now been found that a photopolymer composition containing epoxy compounds, triarylsulfonium hexafluoro antimonite, and tris(trimethylsilyl)silane, solidifies quickly when cured with a gentle UV light of UV LED, while forming a polymer with good mechanical and electric properties. The quickly acting photoinitiator in accordance with the invention, abbreviated QPI throughout the description (QPI standing for Quick Photo Initiator), enabled solidification of 2-3 mm thick layers by UV of 395 nm within 20 seconds or less. The solidification times are lower for a PI according to an exemplary embodiment of the invention than for standard PI employed in the field. In some exemplary embodiments of the invention, cure parameters, including time and thickness, are advantageous for 3D printing formulations.

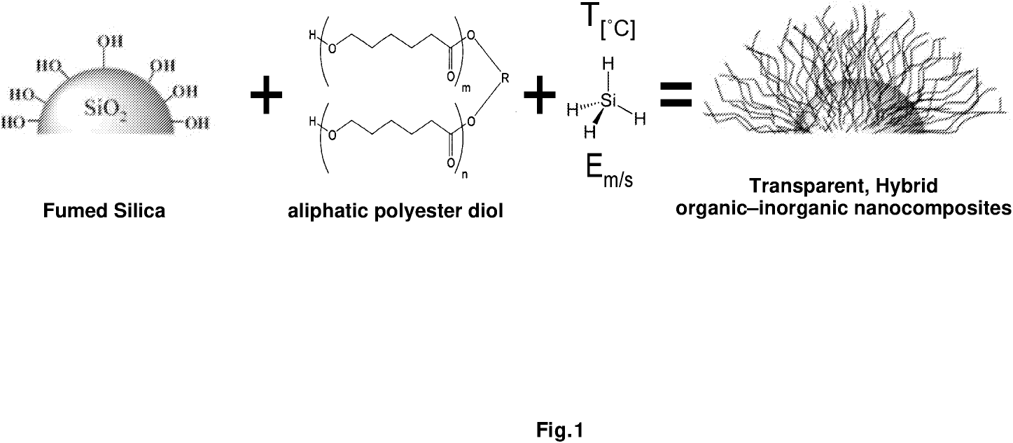

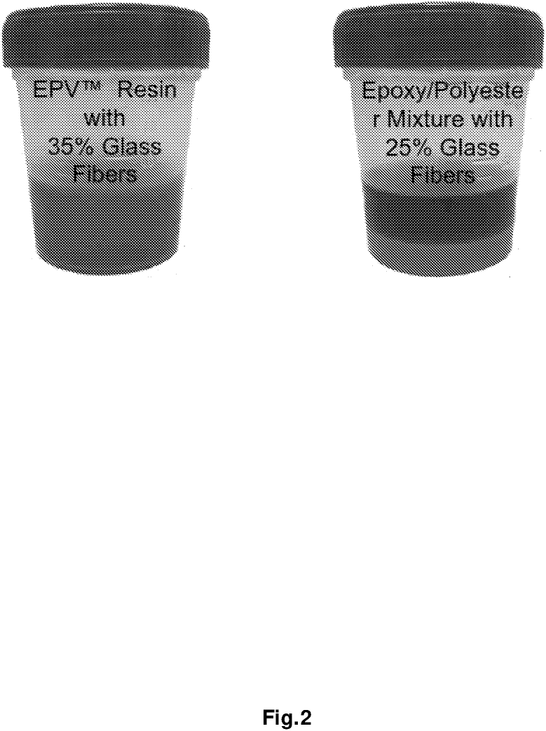

A photopolymer composition according to some embodiments includes at least one cycloaliphatic epoxy compound and a photoinitiator comprising a triarylsulfonium salt is suitable for providing a toughened cured resin, particularly by adding a nano composite toughening agent. In one preferred embodiment of the invention, a photopolymer composition according to the invention, comprising photoinitiator QPI described above, is combined with a SiO₂-Polyester Nano composite Toughening & Anti settling agent based on fumed silica particles whose hydroxyl groups are esterified with fatty acids, preferably via a reaction of silica with a diester of an aliphatic diol polyster. In a preferred embodiment of the invention, said reaction includes adding silane at a higher temperature, while obtaining transparent organic-inorganic nanocomposite (FIG. 1) to be employed as a toughening additive to the photopolymer composition of the invention. The toughener nano composite is added to the composition before curing, resulting in two improved properties: firstly the cured polymer is tougher, and secondly the nanocomposite stabilizes an eventual suspension of glass fiber or other fillers in the composition before curing and prevents settling glass fibers (FIG. 2). The Quick-curing Photopolymer Nanocomposite (QPN) additive, comprising derivatized silica, is used with glass fibers and provides very strong nanocomposite comprising product.

In some exemplary embodiments of the invention, the compositon includes cycloaliphatic epoxy compounds, and a photoinitiator comprising at least triarylsulfonium hexafluoro antimonate, and, in various embodiments of the invention, components selected at least from esters of carboxymethoxy-benzophenone, aliphatic polyester polyols, dibutoxyanthracene, tris(trimethylsilyl)silane, a bisphenol A epoxy compound and acrylic compound, exhibits advantageous features when the composition is UV-cured, particularly when the composition further comprises silica and glass fibers. The advantageous features include fast curing/solidifying, no oxygen inhibition, reduced shrinkage, dark post-cure (which is continuing the cure process after UV initiation even when the light source is removed, “in dark”), whereas the product has high T_{g}, high tensile and flexure strength, good electrical properties (excellent arc and tracking resistance, low dielectric constant and dissipation), UV stability and weatherability due to the aliphatic backbone of the polymer and, moreover, the system exhibits a low skin sensitization due to the high light wavelength. Using LED sources of gentle UV radiation, such as comprising 395 nm, is not only significantly less dangerous from the viewpoint of eventual inadvertent skin irradiation, but it also obviates the elimination of ozone, which is produced by mercury light sources.

Said cycloaliphatic epoxy compounds may include one or more materials selected from EEC, hydrogenated bisphenol A diglycidyl ether (HBD), epoxy acrylates, and others. Said bisphenol A epoxy compound may include one or more materials selected from bisphenol A diglycidyl ether (BADGE), bisphenol F diglycidyl ether (BFDGE), and others. Said acrylic compound may include one or more materials selected from 2-(allyloxymethyl)acrylic acid methyl ester, 2-(allyloxyethyl)acrylic acid methyl ester, and others.

The system of the invention is easy to use, fast cure, and safe, and provides a tough product; the composition before curing has good flowability at room temperature, and it can be stably stored for future use, at least for 2 months, such as at least 3 months or at least 4 months or at least 5 months or at least 6 months. Cationic curing mechanism exhibits curing within seconds under UV LED, or more when employing nano-composite toughening system. The nano-composite toughening system renders the product high impact strength and long term weather resistance. The product and the method for preparing it are non-hazardous and safe for the environment. Photopolymerization system of the invention belongs to green technologies, as it is characterized by low electrical power input and energy requirements, low temperature operation and no volatile organic compound release.

The photoinitiator according to the invention, QPI, may be employed as a hybrid photo/thermal cationic cure initiator providing ultra-fast and also deep curing of cycloaliphatic epoxy resin systems, enabling photo-cure by using UV-LED lamps eventually combined with thermal cure.

The photoinitiator according to the invention, QPI, is a hybrid cationic/free radical photoinitiator for UV LED curable epoxies. In one aspect of the invention, QPI comprises photo energy shifting ingredients, and/or free-radical photoinitiators. The photoinitiator of the invention may comprise a mixture of sulfonium based photo and thermal cure initiators. The photoinitiator of the invention may comprise a color purifying additive, such as ultramarine blue.

In another aspect of the invention, nano based toughener (QPN) for cationic cure cycloaliphatic epoxy systems is employed, comprising an organic-inorganic nanocomposite and exhibiting transparency which makes it advantageously usable for epoxy based UV curing.

The additional objects, advantages, and novel features of various embodiments of the invention will become apparent to one ordinarily skilled in the art upon examination of the following examples, which are not limiting. Additionally, each of the various embodiments and aspects of the present invention as delineated hereinabove and as claimed in the claims section below finds experimental support in the following examples.

### EXAMPLES

Reference is now made to the following examples, which together with the above descriptions, illustrate the invention in a non limiting fashion.

### Materials and Methods

The following materials and methods are used in performance of experiments described in examples hereinbelow:
Triarylsulfonium hexafluoro antimonate (TSHA, such as 50% in 50% material in propylene carbonate of Sigma Aldrich or of Insight High Technology IHT-PI 436);
Ester of carboxymethoxy-benzophenone with poly tetramethylene glycol or with poly methylethylene glycol (ECBP), such as Omnipol BP of IGM Resins;
Tris(trimethylsilyl)silane (TTS);
Antimony hexafluoride based catalyst (AHC) for thermal initiated cationic polymerization, such as K-PURE® CXC-1612 of King Industries;
3,4-Epoxycyclohexylmethyl-3′,4′-epoxycyclohexane carboxylate (EEC), such as Celloxide 2021P of Daicel;
Methylene Blue (MB);
Ester of a polyol such as a dendritic polyester polyol, for example a branched ester of a polyol like PEG with low fatty acids (EP), such as Boltorn® H2004 of Perstorp;
Ultramarine Blue 08 (UMB);
9,10-Dibutoxyanthracene (DBA), for example of Kawasaki Kasei Chemicals Ltd.;
Polyether crosslinkable additive (PEC), such as of BYK Additives & Instruments;
Fumed silica (FS), Aerosil R 805 of Evonic Industries;
Hydrophilic fumed silica, Aerosil 380;
Polyester polyol (PEP), such as of King Industries;
Glycidyloxypropyl)trimethoxysilane (GTS), of Sigma-Aldrich;
Glass fibers (GF);
Hydrogenated bisphenol A diglycidyl ether (HBD), such as of Nagase;
Bisphenol A diglycidyl ether (BADGE), also known as diglycidyl ether of bisphenol A (DGEBA), CAS number 25068-38-6, such as of Sigma; and
2-(allyloxymethyl)acrylic acid methyl ester, also known as methyl 2-((allyloxy)methyl)acrylate, CAS number 219828-90-9.

### Example 1

### Preparation Procedure

In one experiment, a photopolymer composition in accordance with the invention was prepared by performing the following steps.

A) The photoinitiator mixture (mixture 1, abbreviated QPI) was prepared by mixing 2.63 g of TSHA in propylene carbonate 1:1, 0.14 g of silane, 0.81 g of ECBP, and 0.14 g of AH. B) The curing indicator mixture (mixture2) was prepared by dissolving MB in EEC to 0.25 wt% solution.

C) The color purifying solution (mixture 3) was prepared by dissolving UMB to 1% solution in DP.

D) The EEC mixture (mixture 4) was prepared by mixing 29.5 g of EEC, 0.3 g parts of said mixture 2, 0.58 g of PE, and 0.19 g of DBA, while intensively stirring with 1.54 g of.

E) The glycidyl silane mixture (mixture 5) was prepared by mixing 0.53 g of GTS, 22.03 g of PEP, while intensively stirring with 3.98 g of FS at 150° C. for about 30 minutes; and

F) Mixtures 4 and 5 were combined while well stirring for about 15 minutes, followed by admixing 18.0 g of GF, 2.0 g of FS, and 0.6 g of mixture 3, followed by admixing 15.04 g of HBD while mixing at 50° C. for about 10 minutes; followed by adding 3.70 g of QPI (mixture 1) while stirring about 10 more minutes, and adjusting the final viscosity by admixing about 2.00 g of FS.

About 100 g photopolymer composition was obtained and examined during curing with 395 nm UV LED. The composition did not show sensitivity to oxygen, and it quickly solidified, providing a polymer of which mechanical and electric properties were characterized.

Viscosity before curing and thixotropic character of the mixture were found to be between 15,000 cP and 1,000,000 cP, I.T being > 4. The cured material exhibited tensile strength of 74 MPa, elongation 2.5, and hardness D85.

### Example 2

The photoinitiator according to the invention (QPI-2000) and a standard photoinitiator (PI-436) used in the field were employed for curing three resins: A) resin based on EEC prepared as described in Example 1, B) resin based on epoxy-methacrylate, and C) resin based on epoxy-bisphenol A. Three different initiator concentrations in the range of 2-5% were employed, and two different irradiation intensities in the range of about 0.2-0.4 W/cm² were employed. The solidification times were measured, according to visual test and hardness test. The results are presented in following Table 1.

TABLE 1

Cure and solidification times (in seconds) at different initiator concentrations (wt%) and different irradiations (in W/cm²) at wavelength of 395 nm, for different resins and for the initiator of invention (QPI) and for a standard initiator (PI-436)

| | Resin | Resin A | | Resin B | | Resin C | |
|---|---|---|---|---|---|---|---|
| | UV intensity | 0.427 | 0.197 | 0.427 | 0.197 | 0.427 | 0.197 |
| initiator concentration | Cure and solidification times | | | | | | |
| 2% QPI | | 28 | 87 | 36 | 68 | 22 | 52 |
| 3% QPI | | 20 | 60 | 20 | 61 | 16 | 42 |
| 5% QPI | | 15 | 42 | 14 | 50 | 12 | 33 |
| | Resin | Resin A | | Resin B | | Resin C | |
| | UV intensity | 0.427 | 0.197 | 0.427 | 0.197 | 0.427 | 0.197 |
| initiator concentration | Cure and solidification times | | | | | | |
| 2% PI-436 | | 36 | 108 | 55 | 240< | 32 | 69 |
| 3% PI-436 | | 27 | 90 | 36 | 100 | 28 | 57 |
| 5% PI-436 | | 21 | 72 | 21 | 79 | 22 | 48 |

The results clearly show that the photoinitiator according to the invention provides shorter curing/solidification times than the standard intitiator for all resins and all concentrations and all irradiations.

### Example 3

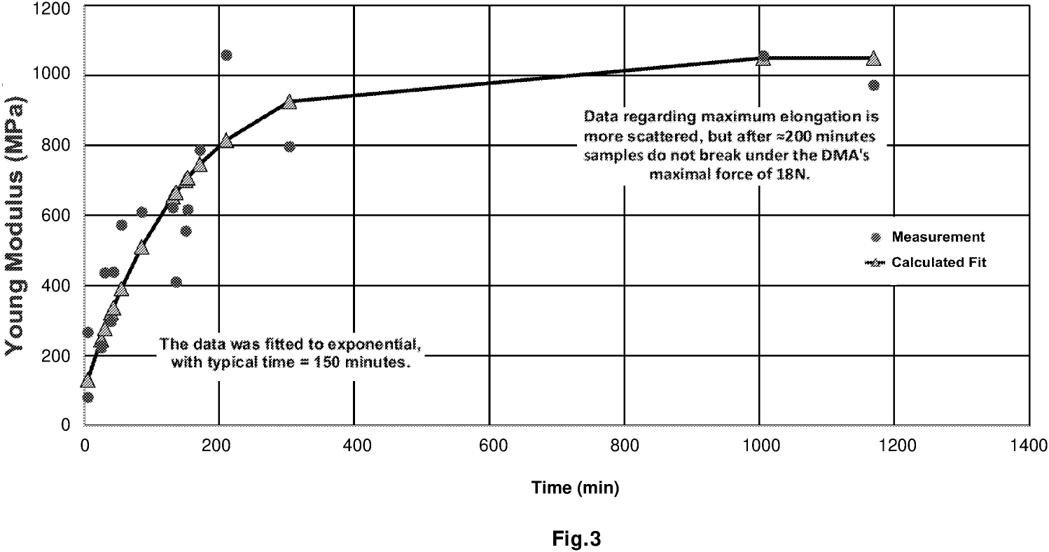

The effect also known as “dark cure”, relating to a phenomena when the photopolymer continues to cure after initial illumination even when the UV LED light source is removed, was verified by evaluating Young modulus vs. time and is presented in FIG. 3. Twenty samples of 1 mm thick layer of a composition as described in Example 1 were exposed for 20 sec to 15 mW/cm² of UV-LED, 395 nm, under air. The samples were then placed in a “black box” in order to prevent additional exposure to illumination. Every 10 min, Young modulus was measured in a sample using DMA (Dynamic Mechanical Analysis) with maximum force of 18 N, at RT. The data, fitted to an exponential, demonstrate that full cure was achieved after approximately 150 min. After about 200 minutes samples do not break under the DMA’s maximal force of 18 N.

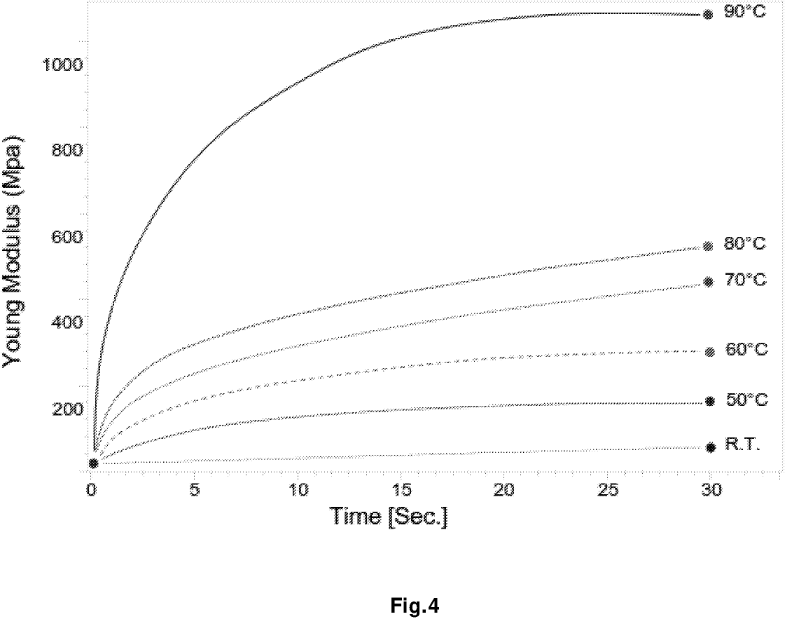

FIG. 4 demonstrates the effect of temperature on the rate of “dark cure”. The experiment described in FIG. 3 was repeated, with DMA measurements at various elevated temperatures. The results presented in FIG. 4 show that exposure to 90° C. will shorten the cure time at “dark cure” from appx 150 min to 30 sec.

### Example 4

Toughened cured polymer was prepared by incorporating the nano-material of the derivatized silica (FIG. 1) into the material as described in Example 1, employing high shear mixing and elevated temperature, while obtaining quickly-cured photopolymer.

Nano based toughener in accordance with one aspect of the invention, was tested and compared with agents generally used for epoxies, including core-shell rubber particles (butadiene/styrene, polybutadiene or acrylate), core shell toughened resins ALBIDUR® (Siloxane), rubber modified epoxies (butadiene-acrylonitrile rubbers / CTBN), thermoplastic granulated or dissolved polymers. (PES, PEEK or PEI), nanosilica containing epoxy resins NANOPOX® (surface modified silica), mineral / inorganic fillers.

The material according to the invention provided better results when measuring material fractures.

### Example 5

### Preparation Procedure

In order to improve impact resistance and increase heat deflection temperature of a resin as describe in Example 1, a photopolymer composition in accordance with the invention was prepared by performing the following steps.

A) The photoinitiator mixture (mixture 1, abbreviated QPI) was prepared by mixing 2.63 g of TSHA in propylene carbonate 1:1, 0.14 g of silane, 0.81 g of ECBP, and 0.14 g of AH.

B) The EEC mixture was prepared by mixing 7 gr of 2-(allyloxymethyl)acrylic acid methyl ester, 0.06 gr of 9,10-Dibutoxyanthracene, 42.5 g of (3′,4′-Epoxycyclohexane)methyl 3,4-epoxycyclohexylcarboxylate( EEC), 5.4 gr of epoxy compound blend (ODP-OH-B0177-02), 5.4 gr of Aliphatic polyester diol with primary hydroxyl groups, 0.75 gr [3-(2,3-epoxypropoxy)propyl]trimethoxysilane, 0.35 gr Polyether.

Mix the above components for approx. 10 min so as to obtain a homogeneous liquid.

C) Add 2 gr of Silane, trimethoxyoctyl-, hydrolysis products with silica make sure proper wetting, slowly add 18 gr of Fibrous glass (composition consisting principally of oxides of silicon, calcium, aluminum, magnesium and boron fused in an amorphous vitreous state), and additional 4 gr of Silane, trimethoxyoctyl-, hydrolysis products with silica. Make sure temp does not exceed 70°C.

D) Add 10 gr of Hydrogenated bisphenol A diglycidyl ether diacrylate and mix well for 10 min. temp of mixture should not exceed 50°C. Finally add 4.0 gr of QPI (mixture 1) while stirring about 10 more minutes.

About 100 g photopolymer composition was obtained and examined during curing with 395 nm UV LED. The composition did not show sensitivity to oxygen, and it quickly solidified, providing a polymer of which mechanical and electric properties were characterized.

Table 2 compares the mechanical properties of two different exemplary embodiments of the invention.

TABLE 2

Comparison of properties of two different exemplary embodiments of the invention

| | Example 1 | Example 5 |
|---|---|---|
| Hardness, ASTM D-2240, Shore D | 85 | 88 |
| Flexural Strength, ASTM D-790, MPa | 27 | 77 |
| Flexural Modulus, ASTM D-790, MPa | 400 | 5501 |
| Izod Impact, ASTM 256, kJ/m² | 2.0 | 3.5 |
| Heat Distortion Point, ISO-75, °C | 77 | 95 |

While the invention has been described using some specific examples, many modifications and variations are possible. It is therefore understood that the invention is not limited in any way, other than by the scope of the appended claims.

It is expected that during the life of this patent many variations thereon will be developed and the scope of the invention includes all such new technologies a priori.

As used herein the term “about” refers to ±10% of the recited value.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

Specifically, a variety of numerical indicators have been utilized. It should be understood that these numerical indicators could vary even further based upon a variety of engineering principles, materials, intended use and designs incorporated into the various embodiments of the invention. Additionally, components and/or actions ascribed to exemplary embodiments of the invention and depicted as a single unit may be divided into subunits. Conversely, components and/or actions ascribed to exemplary embodiments of the invention and depicted as sub-units/individual actions may be combined into a single unit/action with the described/depicted function.

Alternatively, or additionally, features used to describe a method or a process can be used to characterize an apparatus and features used to describe an apparatus can be used to characterize a method or a process.

It should be further understood that the individual features described hereinabove can be combined in all possible combinations and sub-combinations to produce additional embodiments of the invention. The examples given above are exemplary in nature and are not intended to limit the scope of the invention which is defined solely by the following claims.

Each recitation of an embodiment of the invention that includes a specific feature, part, component, module or process is an explicit statement that additional embodiments of the invention not including the recited feature, part, component, module or process exist.

Alternatively or additionally, various exemplary embodiments of the invention exclude any specific feature, part, component, module, process or element which is not specifically disclosed herein.

All publications, references, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

The terms “include”, and “have” and their conjugates as used herein mean “including but not necessarily limited to”.

1. A photopolymer composition comprising at least one cycloaliphatic epoxy compound and a photoinitiator comprising triarylsulfonium hexafluoro antimonate, silane, and an ester of carboxymethoxy-benzophenone with poly methyl ethylene glycol or with poly tetramethylene glycol; wherein said composition is applied in a thickness of at least 1 mm.

2. A photopolymer composition comprising at least one cycloaliphatic epoxy compound and a photoinitiator comprising a triarylsulfonium salt and comprising up to 0.5 wt% antimony hexafluoride.

3. A photopolymer composition comprising at least one cycloaliphatic epoxy compound and a photoinitiator comprising a triarylsulfonium salt and at least one bisphenol A epoxy compound constituting 20-40 wt% of the composition.

4. The photopolymer composition according to claim 3, comprising at least one acrylic compound constituting 5-10 wt% of the composition;
wherein said acrylic compound is 2-(allyloxymethyl)acrylic acid methyl ester.

5. (canceled)

6. The photopolymer composition of claim 1 wherein said cycloaliphatic epoxy compound is 3,4-epoxycyclohexylmethyl-3′,4′-epoxycyclohexane carboxylate (EEC).

7-8. (canceled)

9. The photopolymer composition of claim 1 further comprising at least one component selected from silica, glass fiber, and aliphatic polyester polyol.

10. (canceled)

11. The photopolymer composition of claim 1 further comprising up to 0.5 wt% of dibutoxyanthracene.

12-19. (canceled)

20. The photopolymer composition of claim 1 curable with UV irradiation of a wavelength greater than 350 nm.

21. The photopolymer composition of claim 1 exhibiting solidification of a 2 mm thick layer within 20 seconds, and hardness greater than 80 Shore D (ASTM D-2240).

22-32. (canceled)

33. The photopolymer composition of claim 2, wherein said cycloaliphatic epoxy compound is 3,4-epoxycyclohexylmethyl-3′,4′-epoxycyclohexane carboxylate (EEC).

34. The photopolymer composition of claim 2, further comprising at least one component selected from silica, glass fiber, and aliphatic polyester polyol.

35. The photopolymer composition of claim 2, further comprising up to 0.5 wt% of dibutoxyanthracene.

36. The photopolymer composition of claim 2, curable with UV irradiation of a wavelength greater than 350 nm.

37. The photopolymer composition of claim 2, exhibiting solidification of a 2 mm thick layer within 20 seconds, and hardness greater than 80 Shore D (ASTM D-2240).

38. The photopolymer composition of claim 3, wherein said cycloaliphatic epoxy compound is 3,4-epoxycyclohexylmethyl-3′,4′-epoxycyclohexane carboxylate (EEC).

39. The photopolymer composition of claim 3, further comprising at least one component selected from silica, glass fiber, and aliphatic polyester polyol.

40. The photopolymer composition of claim 3, further comprising up to 0.5 wt% of dibutoxyanthracene.

41. The photopolymer composition of claim 3, curable with UV irradiation of a wavelength greater than 350 nm.

42. The photopolymer composition of claim 3, exhibiting solidification of a 2 mm thick layer within 20 seconds, and hardness greater than 80 Shore D (ASTM D-2240).
